(19) United States
(12) Patent Application Publication
(10) Pub. No.: US 2007/0201234 A1
(43) Pub. Date: Aug. 30, 2007

(54) LUMINOUS ELEMENT

(76) Inventor: Clemens Ottermann, HETTERSHEIM (DE)

Correspondence Address: OHLANDT, GREELEY, RUGGIERO & PERLE, LLP, ONE LANDMARK SQUARE, 10TH FLOOR, STAMFORD, CT, 06901, US

(21) Appl. No.: 10/565,325

(22) PCT Filed: Jul. 19, 2003
(86) PCT No.: PCT/EP04/08047

§ 371 Date: Dec. 26, 2006

(30) Foreign Application Priority Data
Jul. 21, 2003 (DE) 103 33 040.2

(51) Int. Cl. F21V 7/00

(52) U.S. Cl. 362/341

(57) ABSTRACT

The invention provides a luminous element that includes a light-guiding device in which light is guided by reflection. The light-guiding device has at least one light-scattering area with light-scattering structures. The light-scattering structures can be applied to the surface of the light-scattering area. The luminous element also includes at least one light entry surface that is coupled to at least one organic light-emitting diode.

### CROSS-REFERENCE TO RELATED APPLICATIONS

This application claims the benefit under 35 U.S.C. 35 U.S.C. §365 of International Application Serial No. PCT/EP2004/008047, filed Jul. 21, 2003, the entire contents of which are incorporated by reference herein.

### BACKGROUND OF THE INVENTION

1. Field of the Invention

The invention relates to a luminous element, in particular a luminous element with an optical waveguide.

2. Description of Related Art

Luminous elements with light guiding plates are known from the prior art. Light is coupled into the plate and passed on in the plate by total reflection. The light is scattered or coupled out at disturbances, deliberately introduced into the light guiding plate, such as, for example, diffuse scattering centres or sharp contours, such as, for example, at milled indentations. Diffuse luminous surfaces or patterned luminous structures such as, for example, graphic characters have been produced in this way.

Such luminous elements are used, inter alia, for notice boards and advertising boards. Such elements are also used in the automobile sector. In particular, light guiding plates are also used for backlighting LCD displays.

Fluorescent tubes, lamps or light-emitting diodes are generally used for luminous elements with light guiding plates. However, these light sources have a few disadvantages. Fluorescent tubes and lamps are relatively voluminous and are therefore not well suited for producing flat luminous elements. Moreover, only a small fraction of the generated light can be coupled into the plate. Light-emitting diodes and optical fibres constitute point light sources. These lead to an inhomogeneous light distribution in the plate in the event of few, widely separated coupling points. In order to achieve a uniform illumination, there is a need to use a large number of closely neighbouring light-emitting diodes or optical fibres, and this correspondingly renders the luminous elements more expensive and enlarges the dimensions of the light source.

### BRIEF SUMMARY OF THE INVENTION

It is the object of the invention to provide an energy saving luminous element with small dimensions of the light source. This object is already provided in a surprisingly simple way by a luminous element in accordance with the present disclosure.

Consequently, an inventive luminous element comprises a light-guiding device in which light is guided by reflection, in particular, and in the case of which the light-guiding device has at least one light-scattering area with light-scattering structures, and/or in the case of which light-scattering structures can be applied, in particular to the surface of the light-scattering area. The luminous element also comprises at least one light entry surface which is coupled to at least one organic light-emitting diode (OLED).

Reflection is understood in this context both as reflection at metallically reflecting surfaces, and as total or partial reflection at an optically thinner medium.

OLEDs can be produced in a very flat fashion and with a large surface, and their form can be adapted in a simple way and/or be tailored to the application. By coupling an appropriately formed OLED, it is therefore possible to achieve a uniform illumination of the light-guiding device without a substantial enlargement of the dimensions of the luminous element.

The invention is outstandingly suitable for a multiplicity of applications. For example, an inventive luminous element can be used in display technology as backlighting of LCD display screens, for example in mobile telephones, PDA units or notebooks. Other applications of the luminous elements are, for example, their use as display panels, annunciators or luminous panels for advertising purposes or in air traffic and road traffic, as switch illuminations and sensor illuminations, as large-area illumination sources for interior lighting, for ambient lighting, as emergency lighting or as transportable and light luminaries in the outdoor sector. The invention can also be used to produce compact cold-light sources, for example for optical microscopes.

Whereas OLEDs generally cannot be produced in arbitrary shapes, according to the invention virtually arbitrarily shaped luminous elements can be provided with the aid of appropriately shaped light-guiding devices.

OLEDs can already be produced with very good internal quantum efficiencies (number of photons per injected electron). Thus, OLED layer structures with internal quantum efficiencies of 85% are already known. However, the efficiency of OLEDs is reduced substantially by the outcoupiling losses. Reflection losses occur at the existing interfaces of mutually adjoining media with different refractive indices. Especially, there is a particularly high jump in refractive index during outcoupling at the surface of the OLED. This jump in refractive index leads to total reflection of light which, coming from the interior of the OLED, strikes the interface at an angle which is greater than the critical angle. This, in turn, reduces the solid angle at which the radiation can be outcoupled.

This disadvantage of OLEDs is avoided, however, in the case of the luminous element according to the invention. Owing to the direct coupling of the OLED to the light-guiding device, a larger jump in refractive index at an air/OLED interface is circumvented, in particular, when the light-guiding element comprises a transparent material which is coupled to the OLED or is in contact therewith.

The light of the OLED can thus be coupled into the light-guiding element and may pass on there by using the good internal quantum efficiency. Glass and/or plastic and/or a fluid, for example, can be used as transparent material. Scratch-resistant elements and light-guiding elements of high optical quality can be produced using glasses. Plastics are good value and light and can be used to produce flexible luminous elements. Fluids can also be used as transparent, light-guiding material, for example in a suitable transparent housing. The term fluid within the meaning of this invention is used here both for liquids and for gases or gels.

In accordance with one embodiment of the invention, the light-guiding device comprises a light guiding plate or film. One or both sides of the plate and/or one or more of the edge surfaces of the plate can serve here as light exit surfaces. The light entry surface can be arranged at an edge surface or else on a side of the light guiding plate. In this context, the term side is used for the large surfaces which run in a fashion substantially parallel to one another, and the term edge surface is used for one of the narrow surfaces at the edge running around one of the sides. In accordance with one embodiment, the light entry surface in this case adjoins an edge surface of the plate such that the OLED is arranged as far as possible at the rim of the plate and thereby occupies little surface area useful for the light-scattering area.

However, other shapes such as, for example, cylindrical, semicylindrical, tubular, conical or prismatic shapes, as well as combinations of these shapes are also possible and advantageous for specific applications.

In accordance with one further embodiment of the invention, the light-guiding device generally has an elongated shape. This can, for example, likewise be cylindrical, conical or prismatic.

One development of this embodiment provides that the light entry surface comprises at least one end face or at least one face at one of the ends of the light-guiding device. For example, the light entry surface can be arranged in a region, abutting an end face, of the lateral surface at an end of a cylindrically, semicylindrically or prismatically elongated light-guiding device.

However, in accordance with another development of the invention, the OLED can also be arranged on a lateral surface. The OLED can also be fitted in this case off the edge surfaces or end faces of the light-guiding device such that the light can, for example, propagate along oppositely directed light guidance directions along the light-guiding device. What is thought of in this regard, inter alia, is a central arrangement of the OLED on a, for example, round or square plate-shaped light-guiding device, the light being able then to propagate along radially running light guidance directions towards the rim, or the edge surface of the device.

In accordance with one further embodiment, a luminous element according to the invention can also have a light-guiding device of annularly bent shape. Given a suitable arrangement and density of the light-scattering structures, it is then possible to provide an annular luminaire, for example.

in one further embodiment of the invention, the OLED is coupled to the light entry surface via a coupling element. The use of a coupling element uses multivarious further options for fashioning luminous elements according to the invention. Thus, for example, a number of OLEDs can be coupled to a light entry surface via a coupling element in order, for example, to increase the luminosity of the luminous element. In accordance with one development of the invention, the several OLEDs can also emit light of different colour. This is favourable, for example, in order to mix white light, for example by means of blue, red and green OLEDs, or to mix light with a specific colour sensation which can be produced only with difficulty by means of a single OLED. Of course, it is also possible to make advantageous use of an OLED which already emits white light.

The coupling element can also have at least two different coupling surfaces. These can differ from one another in shape and surface area such that the coupling element serves as shape converters. It is possible in this way, for example, to adapt prefabricated OLEDs of fixed shape to different light entry surfaces. For example, an OLED can be coupled to a light entry surface which is smaller than the luminous area of the OLED. Of course, it is also inversely possible for an OLED to be coupled to a light entry surface of the light-guiding device which is larger than the luminous area of the OLED, the coupling element then serving as distributor for the light emitted by the OLED.

OLEDs are frequently produced on transparent substrates such as, in particular, glass substrates, coated glass substrates, glass/plastic laminates or plastic substrates, the light generated by the electroluminescence layer of the OLED being guided through this substrate. The luminous element can then advantageously be assembled by coupling the transparent substrate to the light entry surface of the light-guiding device. If a flat, plate-shaped glass substrate is used, as is widely the case for luminous elements in, for example, backlighting devices of LCD displays, it is possible to couple it both to an edge surface of the substrate and to the front side thereof which is situated opposite the surface on which the OLED layers are applied.

In order, for example, to obtain a good adaptation of the shape of the OLED to the shape of the light entry surface of the light-guiding device, it is also possible for the substrate of the OLED to be flexible in accordance with one embodiment of the invention. This allows, for example, an OLED also to be coupled with good contact to cambered light entry surfaces, for example to the lateral surface of a cylindrical light-guiding device.

Suitable as substrate to this end, for example, is a polymer substrate, extremely thin glass or a composite of extremely thin glass and polymer. These materials also have the advantage that the OLEDs produced therewith are very flat, and therefore the dimensions of the luminous element according to the invention are not substantially enlarged. A composite of extremely thin glass and polymer can comprise, for example, a polymer-coated or polymer-laminated extremely thin glass. A polymer plate or polymer film can be used as polymer substrate.

The OLED can, for example, be coupled to the light-guiding device by a transparent bonded joint, in particular by a transparent bonded joint matched for refractive power. This avoids air gaps between the OLED and light-guiding device, and thus provides a particularly lossless coupling.

However, in accordance with one further embodiment it is also possible for the layers of the OLED to be applied directly to the light entry surface of the light-guiding device. This is advantageous, in particular, for the mass production of small luminous elements, since it is thereby possible to omit the coupling and aligning of the OLED.

It is favourable, furthermore, when the light emitted by the OLED is coupled in such a manner that it propagates in the light-guiding device as much as possible along the light guidance direction provided. As a result, for example, there is a reduction in losses owing to overshooting of the critical angle for total reflection, as well as owing to propagation counter to this direction. This can be achieved, inter alia, in that a light entry area which comprises the light entry surface, and/or the OLED have/has at least one specular reflective surface and/or an optical grating. Given a suitable arrangement, the light can be deflected at these devices in the direction of the light guidance direction provided.

A strip-shaped OLED is expedient for many embodiments. This is advantageous, in particular, for flat luminous elements in which the light entry area runs along an edge of the light-guiding device. Moreover, given such a strip-shaped form the OLED can also have contact surfaces which extend along the longitudinal sides or along the longitudinal direction of the strip-shaped OLED. Preferably, the contact surfaces are likewise of strip-form in this case. The contact surfaces can comprise a metal layer or an electrically conducting polymer layer, for example.

Consequently, voltage is supplied to the layers of the OLED in a fashion transverse to the longitudinal direction, and the current paths become correspondingly short. Voltage drops along the layers of the OLED can thereby be minimized, and a uniform luminous density can be achieved.

Furthermore, the light entry surface can be arranged obliquely to the light guidance direction. It is thereby possible to enlarge the light entry surface by comparison with a perpendicular arrangement in relation to the light guidance direction. An OLED of larger area can also be coupled correspondingly, it thereby being possible to increase the luminous intensity of the element. The average direction of light propagation is understood as the light guidance direction in this case. The component beams can, however, certainly run at an angle to this direction and be reflected at the surface of the light-guiding device such that they follow a zigzag path about this direction. Moreover, owing to the oblique arrangement it is possible to adapt the angular distribution of the light reflected by the OLED to the critical angle of total reflection in the light-guiding device, and to optimize it.

Moreover, the angular distribution of the emitted light can also be adapted with the aid of a suitably curved light entry surface. For example, the light entry surface can be curved concavely or convexly or in the shape of a cylindrical lens.

In the light-scattering area, the light-guiding device can have one or more scattering structures in the interior. The scattering structures can change the direction of light propagation of a light beam striking the structure such that in this case said light beam exceeds the critical angle for total reflection when next impinging on a surface of the light-guiding device, and thus passes to the outside.

The light-scattering structure can also comprise a roughened surface area. This provides a stochastic distribution of the local surface normals to the surface. Consequently, the critical angle of total reflection can be exceeded locally here, as well, for a certain fraction of the guided light such that this fraction is scattered out of the light-guiding structure, and a diffuse scattering of the light is achieved. The roughness can also rise along the light guidance direction. The light intensity decreasing along the light guidance direction owing to being scattered out is thereby compensated. A homogeneously luminous surface such as is desired, for example, for backlighting is achieved in this way.

In addition to roughened surface areas, other forms of light-scattering structures are also advantageously possible. For example, the light-scattering structure can also comprise a raised pyramid structure and/or a recessed pyramid structure and/or a convex lens and/or a concave lens and/or a raised prism and/or a recessed prism and/or a convex cylindrical lens and/or a concave cylindrical lens. Such optical elements as light-scattering structures have the advantage, inter alia, that the light can be coupled out substantially on that side on which these elements are arranged.

The light-scattering structure can advantageously also be coloured, in order to influence the colour sensation of the light scattered out.

Light-scattering structures suitable for a luminous element according to the invention can be produced in multivarious ways. For example, raised structures can be produced in a simple way by printing the surface of the light-guiding device. Roughened surface areas as a light-scattering structure can be produced, inter alia, by grinding, sandblasting or etching. Etching is also generally suitable for producing recessed light-scattering structures. Light-scattering structures can also be embossed into the surface of the light-scattering area of the light-guiding device 3.

Optical gratings of varied configuration can also advantageously serve as light-scattering structures. A suitable grating can be designed in this case both in terms of one dimension, for example as a multiline grating, and in two dimensions as a raster or point grating. The direction of the light scattered out can, in particular, also be advantageously influenced by a blazed grating.

In accordance with one embodiment of the invention, the light-scattering area has a light exit surface which is larger than the light entry surface of the light-guiding device. In the case of a plate or film as light-guiding device and of an edge surface as light entry surface, for example, the surface of the light-scattering area can even be substantially larger than the light entry surface.

The light-guiding device can also have a light exit surface which comprises at least one edge surface of a light guiding plate. It is therefore possible to achieve a high luminous density at the light exit surface when the light exit surface is smaller than the luminous area of the OLED or the light entry surface of the light-guiding device.

### BRIEF DESCRIPTION OF THE SEVERAL VIEWS OF THE DRAWINGS

The invention is explained in more detail below with the aid of preferred embodiments and with reference to the attached drawings. Here, identical reference numerals refer to identical or similar parts.

FIG. 1 shows a first embodiment of the invention with coupling via a glass substrate of the OLED,

FIG. 2 shows a second embodiment of the invention in which the layers of the OLED are applied directly to the light-guiding device,

FIGS. 3A to 3D show developments of the embodiment shown in FIG. 2,

FIGS. 4 and 5 show further embodiments of the invention with coupling via a glass substrate of the OLED,

FIG. 6 shows an embodiment with an oblique arrangement of the OLED at an edge surface of the light-guiding device,

FIGS. 7A and 7B show embodiments of luminous elements according to the invention with an arrangement of the OLED on a lateral surface of a plate-shaped light-guiding device,

FIGS. 8A to 8C show embodiments with a curved light entry surface,

FIGS. 9A and 9B show exemplary embodiments of strip-shaped OLEDs with lateral contact surfaces,

FIGS. 10A to 10G show embodiments of a luminous element according to the invention with differently shaped light-guiding devices,

FIG. 11 shows an embodiment with a fluid-filled light-guiding device,

FIG. 12A to 12F show a perspective view of sections from the light-scattering area of the light-guiding device,

FIG. 13A to 13C show embodiments with a coupling element,

FIG. 14 shows an embodiment of an annular luminous element, and

FIGS. 15A and 15B show two embodiments of luminous elements with a light exit surface at an edge surface of the light-guiding device.

### DETAILED DESCRIPTION OF THE INVENTION

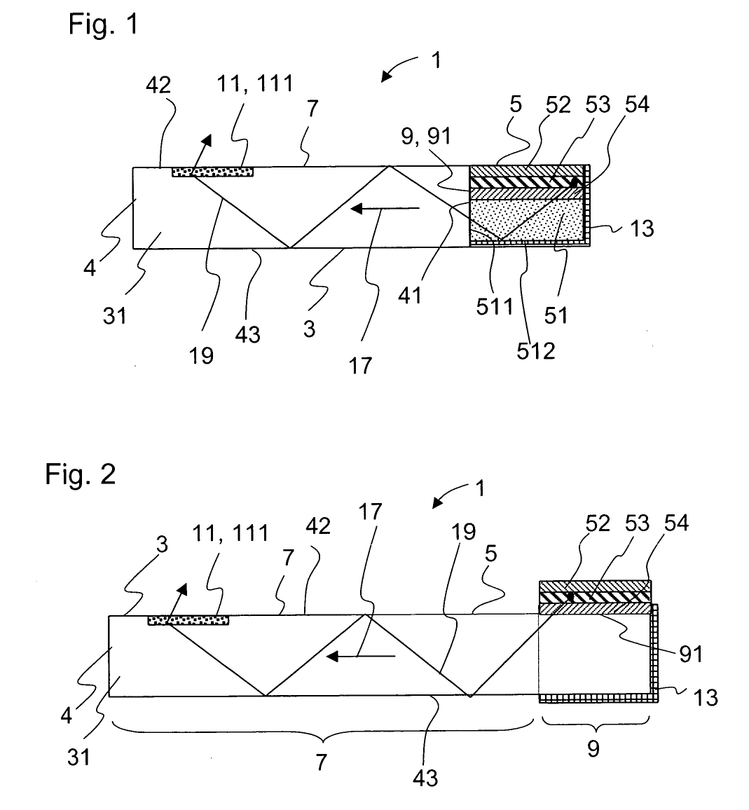

FIG. 1 illustrates a schematic sectional view through a first embodiment of a luminous element according to the invention which is denoted as a whole by the reference numeral 1.

The luminous element 1 comprises a light-guiding device 3 in which light is guided by reflection. The light-guiding device 3 has a light-scattering area 7 and a light entry area 9 with a light entry surface 91. The light-guiding device 3 comprises a light guiding plate 4 with sides 42, 43 and narrow edge surfaces or lateral edges 41. In this embodiment, the light entry surface 91 is arranged at an edge surface 41 of the light guiding plate 4. It is also advantageously possible to use a film instead of a plate 4.

An OLED denoted as a whole by 5 is coupled to the light entry surface 91. In this embodiment, the OLED comprises a transparent substrate 51, for example made from glass, to which the OLED layers 52, 53 and 54 are applied.

The layers 52 and 54 are electrode layers for supplying power to one or more electroluminescent layers 53 arranged between these layers. The electrode layer 54 in contact with the substrate 51 is embodied in this case as a transparent, or at least partially transparent electrode layer such that light which is emitted by the electroluminescent layer 53 can pass into the glass substrate through the electrode layer 54. Indium tin oxide or another conductive or semiconducting material which, as a thin layer, is at least partially transparent to the light emitted by the electroluminescent layer is used in general for the electrode layer 54. In addition to indium tin oxide, it is thus also possible to use a thin metal layer, for example. Gold or a gold alloy, inter alia, is suitable to this end.

On the basis of the difference in work function between the electrode layers 52 and 54, and given a correct polarity of the voltage applied to the layers 52 and 54, electrodes are injected at the layer acting as cathode into an unoccupied electronic state of the organic, electroluminescent material. At the same time, holes are injected from the layer, acting as anode, with a lower work function, as a result of which light quanta are emitted in the organic material by recombination of the electrons with the holes.

The construction, the composition and the sequence of the OLED layers is known to the person skilled in the art. It goes without saying that any OLED layer structure known from the prior art can be used for the invention.

Electroluminescent polymer materials or so-called small molecules, for example, can be used as material for an electroluminescent layer of the OLED. As organic, electroluminescent material, these materials can have, inter alia, MEH-PPV ((poly(2-methoxy, 5-(2′-ethyl-hexyloxy) paraphenylene vinylene) or else Alq₃ (tris-(8-hydroxyquinolino)-aluminium). In the meantime, a multiplicity of suitable electroluminescent materials such as, for example, organometallic complexes, in particular triplet emitters or lanthanide complexes, have become known. Such layers and materials as well as various possible layer sequences within organic, electro-optical elements such as, in particular, of OLEDs are described in the following documents and in the quotations of the literature described therein, which are also completely incorporated in the present application by reference: Nature, Vol. 405, pages 661-664, Adv. Mater. 2000, 12, No. 4, pages 265-269, EP 0573549, U.S. Pat. No. 6,107,452, U.S. Pat. No. 6,365,270, U.S. Pat. No. 6,333,521, U.S. Pat. No. 6,515,298, U.S. Pat. No. 6,498,049, U.S. Pat. No. 6,384,528.

The electrode layers 52 and 54 generally have different work functions and so a difference in work function arises between the two layers.

Better quantum yields can, moreover, be achieved with an OLED when further functional layers are arranged between the electrode layers in addition to the active electroluminescent layer 53. Hole injection layers, potential matching layers, electron blocker layers, hole blocker layers, electron conductor layers and/or electron injection layers, for example, can be present in the OLED as further functional layers. Function, arrangement and composition are known in this case from the specialist literature.

The glass substrate 51 to which the OLED layers 52, 53 and 54 are applied is in the shape of a plate. In the case of the embodiment illustrated in FIG. 1, here the glass substrate 51 is coupled to the light-guiding device, or the light-guiding element 3 not with the front side 512, which is opposite the side with the OLED layers 52, 53 and 54 and via which otherwise the light is usually coupled out in the case of an OLED, but with an edge surface 511. This arrangement permits a flat construction.

In order to raise the incoupling efficiency, the glass substrate of the OLED is additionally provided with a specular reflection layer 13 which is advantageously free from absorption or poor in absorption for the wavelengths of the light emitted by the OLED 5.

A light beam which is emitted by the OLED 5 is coupled into the light-guiding device 3 via the light entry surface 91 and is reflected to and fro by total reflection at and between the sides 42 and 43 and guided along the light guidance direction 17 through the light-scattering area 7 of the light-guiding device. The light scattering area 7 has one or more light-scattering structures 11. For example, such a light-scattering structure 11 can, as in FIG. 1, comprise a roughened surface area on one of the two sides 42, 43. The light striking this surface area is partially scattered out because of the stochastic distribution of the surface normals in this area 111, since the critical angle for total reflection is exceeded for some component beams such as in the case of the component beam 19. The area on the side 42 with the light-scattering structure(s) 11 in this case forms a light exit surface 6 of the luminous element 1.

A further embodiment of a luminous element according to the invention is illustrated in FIG. 2. In this embodiment, layers 52, 53 and 54 of the OLED 5 are applied directly to the light entry surface 91 of the light-guiding element, or of the light-guiding device 3. Consequently, the OLED 5 needs no glass substrate as carrier, since here the light-guiding device 3, or the light guiding plate 4, is itself used as carrier for the OLED layers.

Moreover, the light entry surface 91 is arranged not at an edge surface, as with the exemplary embodiment illustrated in FIG. 1, but on a side of the light guiding plate 4. The light entry surface 91 also adjoins an edge surface.

At a light entry area 9 which also comprises the light entry surface 91, the light-guiding device 3 is provided with a specular reflective layer 13, in order to enlarge the fraction of the light guided in the light-guiding device 3.

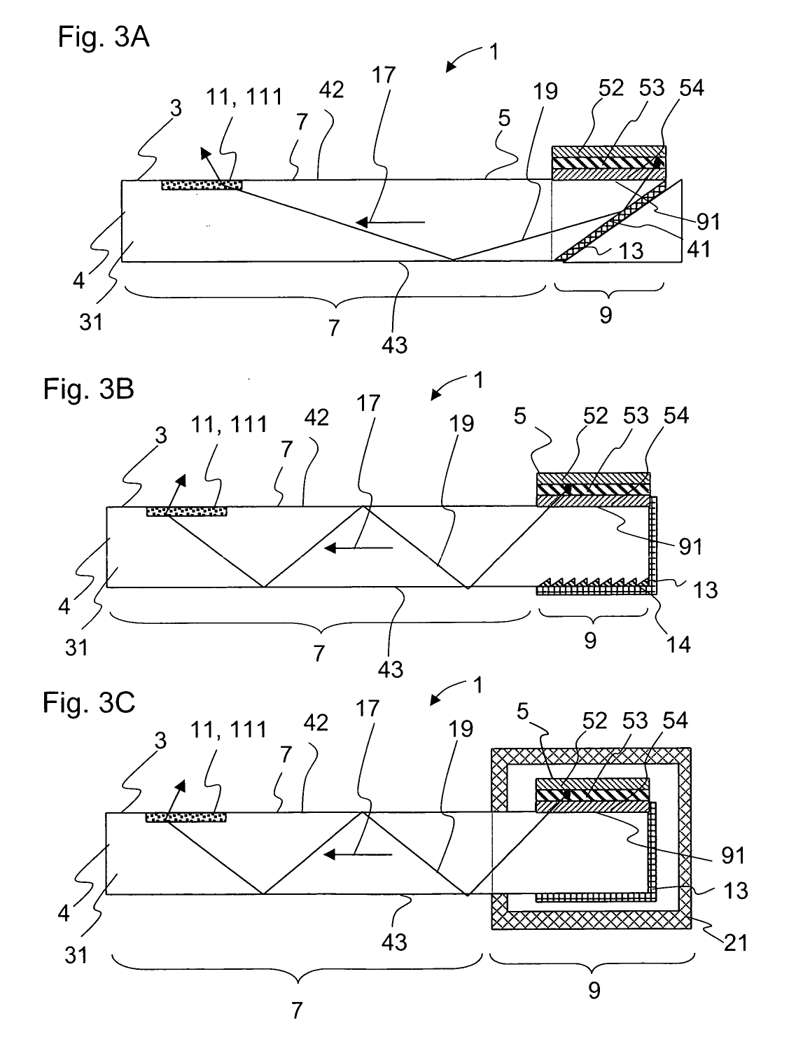

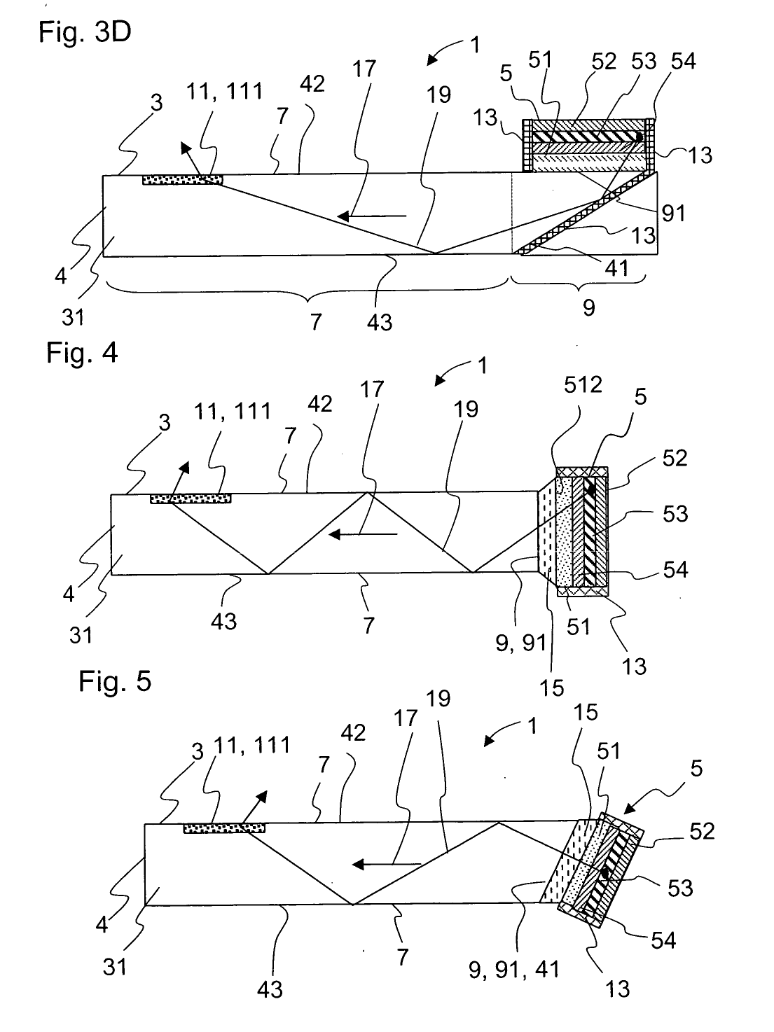

FIG. 3A shows a development of the embodiment illustrated in FIG. 2. The light entry area 9 of the light-guiding device 3 in this development comprises an edge surface 41 which is bevelled. This edge surface 41 is consequently arranged obliquely both to the light entry surface 9 and to the light-guiding device 7. A specular reflective layer 13 is applied to the edge surface 41. Consequently, light beams which are emitted by the OLED and strike the edge surface 41 with the reflective layer 13 are reflected such that the component of the direction of propagation perpendicular to the light guidance direction 17 is deflected into a component along the light guidance direction.

FIG. 3B likewise shows a development of the embodiment illustrated in FIG. 2. Here, a grating 14 onto which a portion of the light emitted by the OLED falls is arranged in the light entry area 9. The grating likewise leads to a deflection of the light in the direction of light guidance. The grating constant can advantageously be matched in this case to the wavelength emitted by the OLED and the angular range between the critical angles of the light-guiding device 3, or to the numerical aperture thereof. In order to suppress the scattering by the grating 14 contrary to the light guidance direction, the grating can also be designed, in particular, as a blaze grating. For example, the grating 14 can be bonded onto or embossed into the light-guiding device.

A yet further development of the embodiment shown in FIG. 2 is illustrated in FIG. 3C. The light entry area 9 of the embodiment illustrated in FIG. 3 is surrounded by a housing 21 which protects the OLED 5 and the reflective layer 13 against damage. The housing 21 can also serve as encapsulation for protecting the OLED 5 against moisture and reactive air constituents. In order to improve the encapsulation, the drying agent which absorbs penetrating moisture can also be present in the space enclosed by the housing 21. The housing can also advantageously be equipped with reflecting inner walls in order to reduce losses during incoupling.

FIG. 3D shows a variant of the embodiment, shown in FIG. 3A, of a luminous element 1 according to the invention. In this variant, the OLED comprises a transparent substrate 51 to which the OLED layers 52 to 54 are applied. The transparent substrate 51 of the OLED 5 is coupled to the light entry surface 91 of the light entry area 9. In order to increase the incoupling efficiency, in the case of this embodiment, as well, an edge surface 41 of the light-guiding device 3 is bevelled and provided with a reflective layer. The OLED 5, as well, in particular its transparent substrate 5, is provided with reflective layers 13 on the edge surfaces.

In order to keep the overall height low, it is advantageously possible to use as substrate 51 of the OLED an extremely thin glass or a polymer film, for example with a thickness in the region of <150 μm, or another transparent, thin substrate. Such a substrate can also, for example, be an extremely thin glass/polymer laminate or a similar composite material. Coupling the OLED 5 to the light entry surface 91 via a glass substrate 51 of the OLED as illustrated by way of example in FIG. 3D is attended by the advantage that the OLED 5 can be produced separately. Moreover, this also enables an exchange of the OLED 5 given a suitable releasable coupling.

FIG. 4 shows a further embodiment of the luminous element 1 according to the invention. in a way similar to the case of the luminous element 1 illustrated with the aid of FIG. 1, in this embodiment the OLED is applied to a substrate 51 which is coupled to the light-guiding device 3. In the embodiment shown in FIG. 4, the light-guiding device 3 likewise comprises a light guiding plate 4 with sides 42, 43 and edge surfaces 41.

Just as in the case of the luminous element shown in FIG. 1, the light entry surface 91 is arranged at one of the edge surfaces 41. In a departure from the luminous element shown in FIG. 1, in the embodiment illustrated in FIG. 4 the front side 512 of the glass substrate 51 of the OLED 5 is coupled to the light entry surface 91. The coupling of the OLED to the light-guiding device 3, for example at the light entry surface 91 thereof, is performed via a transparent bonded joint 15. The bonded joint 15 can be matched for refractive power, in particular, in order to avoid reflection losses.

In the exemplary embodiment illustrated in FIG. 4, the light entry surface lies on an edge surface of the light-guiding device 3, the edge height being smaller than the height of the luminous surface of the OLED 5. Other than illustrated in FIG. 4, however, it is also possible for an OLED which has a smaller height than the edge height of the light-guiding device to be coupled to the light entry surface.

Likewise illustrated in FIG. 5 is an embodiment of the OLED with incoupling of the light via a light entry surface 91 arranged at an edge surface 41. Here, as well, the OLED 5 comprises a glass substrate 51 to which the OLED layers 52, 53 and 54 are applied. The OLED 5 is coupled to the light entry surface 91 by means of a transparent bonded joint 15. In a departure from the embodiment illustrated with the aid of FIG. 4, however, here the light entry surface 91 is fitted on the light guiding plate obliquely to the light guidance direction 17. A bevelled edge surface as light entry surface such as the exemplary embodiment illustrated in FIG. 5 has is, moreover, advantageous in order to be able to couple a wider OLED to a flatter plate-shaped light-guiding device.

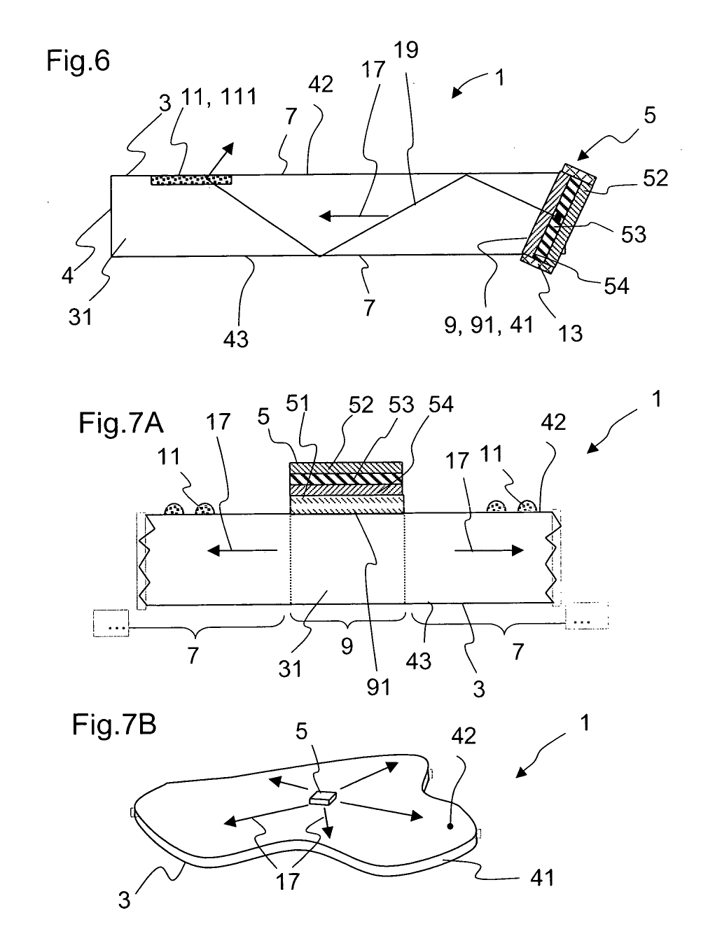

Like FIG. 5, FIG. 6 shows an embodiment with an oblique arrangement of the OLED on an edge surface 41 of the light-guiding device 3, or the light guiding plate 4. In the embodiment shown in FIG. 6, the OLED layers 52, 53 and 54 are however applied not to a glass substrate coupled to the light-guiding device, but directly to the light entry surface 91 arranged obliquely to the light guidance direction 17 at an edge surface 41.

In the embodiments of FIG. 4 to FIG. 6, the light entry surface 91 also simultaneously forms the light entry area 9.

In the embodiments so far illustrated with the aid of FIGS. 1 to 6, the OLED is arranged on or in the region of an edge surface of the light-guiding device. Just as with the exemplary embodiments of FIGS. 2 and 3A to 3D, in the exemplary embodiments shown with the aid of FIGS. 7A and 7B the OLED is arranged on a lateral surface of a plate-shaped or flat light-guiding device, which can also be curved. In a departure from the embodiments described above, however, the OLED is located here off the edge surfaces.

In detail, FIG. 7A shows a sectional illustration of a section of a luminous element 1 according to the invention. The light entry area 9 is formed in this case by that area of the light-guiding device which is covered by the OLED 5. The light emitted by the OLED 5 and coupled into the light entry area 9 through the light entry surface 91 on the side 42 is then guided away from the OLED along opposite light guidance directions through the plate-shaped light-guiding device 3. Moreover, in the case of this embodiment, the light-scattering structures 11 are applied to the surface of the light-scattering areas 7. This can be performed, for example, by printing with the aid of a suitable transparent varnish.

FIG. 7B shows a perspective view of such an embodiment. The OLED 5 of the luminous element 1 is arranged centrally on a side 42 of a plate-shaped or flat light-guiding device 3. The light-guiding device 3 can have any desired border shape. Other than as illustrated in FIG. 7B, the light-guiding device 3 can also be, for example, round, square or rectangular. The light emitted by the OLED 5 then propagates in the light-guiding device along light guidance directions 17 emanating radially from the OLED 5. Of course, it is also possible for a number of OLEDs of the same or different colour and which can be driven jointly or else separately to be arranged in a nearby or separate fashion on a light guidance device.

However, in accordance with another development of the invention, the OLED can also be arranged on a lateral surface. In this case, the OLED can also be fitted off the edge surfaces or end faces of the light-guiding device such that the light can, for example, propagate along oppositely directed light guidance directions along the light-guiding device. What is in mind in this regard is, inter alia, a central arrangement of the OLED on a for example round or square plate-shaped light-guiding device, the light then being able to propagate along radially running light guidance directions towards the rim, or the edge surface of the device.

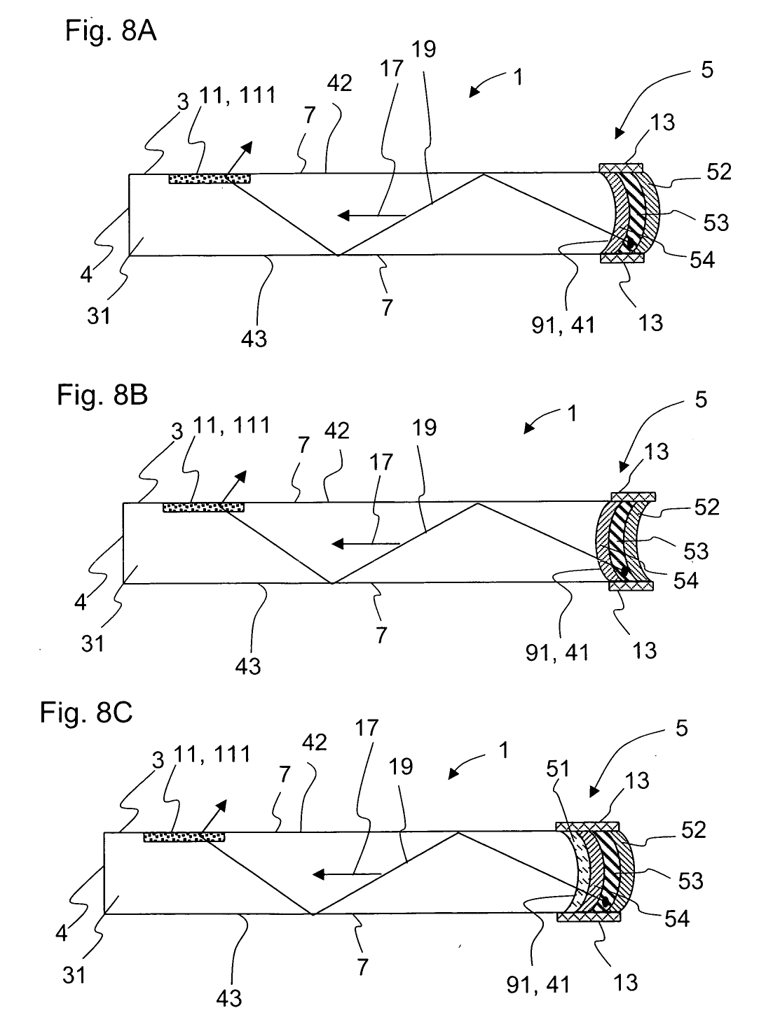

The light entry surface 91 must not be a flat surface. FIGS. 8A and 8B show two exemplary embodiments with curved light entry surfaces 91. In the case of the luminous elements illustrated in these figures, the light entry surface is respectively arranged at an edge surface 41 of a light guiding plate 4. Here, the embodiment shown in FIG. 8A has a light entry surface 91 which is convexly curved with reference to the outer region of the light-guiding device 3, or the plate 4, and the embodiment illustrated in FIG. 8B has a concavely curved light entry surface.

The curved light entry surface can develop a lens effect if the refractive indices of an electroluminescent layer 53 and the interior 31 of the light-guiding device 3 differ from one another. Depending on which of the refractive indices is greater, both the convexly curved and the concavely curved light entry surface can act in a divergent or convergent fashion. The light entry surface 91 can be curved in one direction as with a cylindrical lens, or else in two directions.

FIG. 8C shows a modification of the embodiment, illustrated in FIG. 8A, of a luminous element 1 according to the invention. In this embodiment, the layers 52-54 of the OLED 5 are not applied directly to the light entry surface 91 but, In a way similar to those in FIGS. 1, 3D, 4 or 5, the OLED 5 is prefabricated using a substrate 51 and then coupled to the light entry surface 91. In the embodiment shown in FIG. 8C, the substrate is sufficiently flexible to be able to adapt to the curvature of the light entry surface 91, which is a constituent of the curved edge surface 41. An extremely thin glass, a polymer film or else an extremely thin glass/polymer composite can expediently be used as substrate therefor.

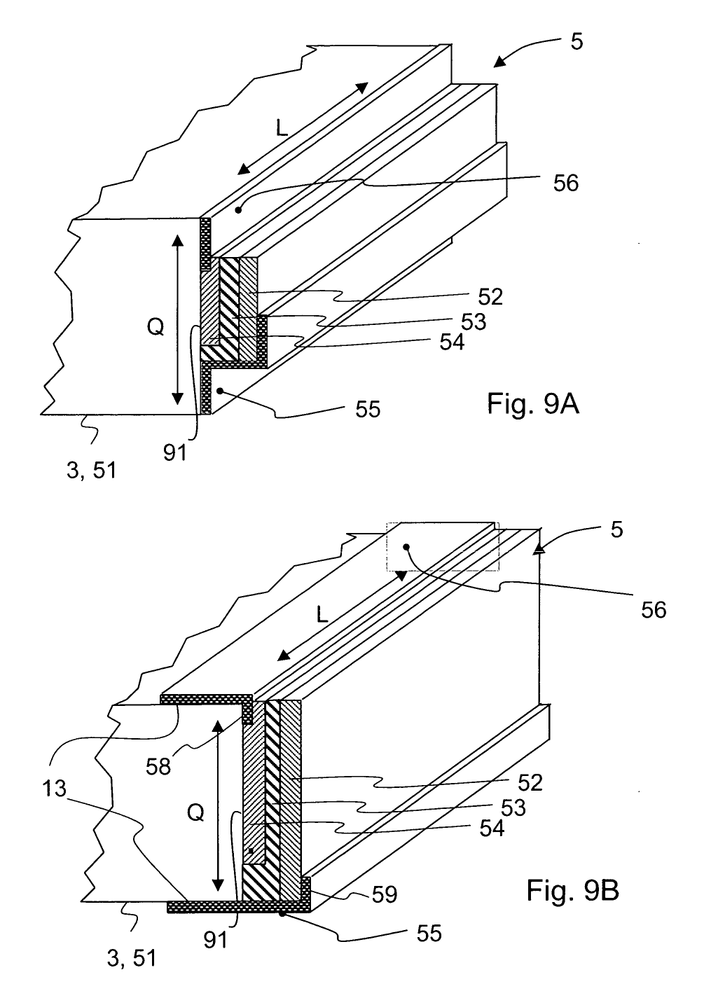

Exemplary embodiments of strip-shaped OLEDs 5 such as can be used for one of the abovedescribed embodiments are illustrated in FIGS. 9A and 9B. The layers 52, 53 and 54 of the OLED are applied in this case to a glass substrate 51, or directed to a surface of the light-guiding device 3. Lateral contact surfaces 55 and 56 which extend along the longitudinal direction L of the strip-shaped OLED 5 are used in this case to make contact with the electrode layers 52 and 54. The contact surfaces 55 and 56 have a good conductivity, and so along the longitudinal direction L substantially no voltage drops across the electrode layers 52 and 54 and no electrical power is lost. This effect would otherwise occur, in particular, with the use of an indium tin oxide layer as transparent electrode layer 54 with a relatively high resistivity. The contact surfaces 55 and 56 therefore serve as busbars for supporting the conductivity of the electrode layers 52, 54 of the OLED 5.

In the case of both exemplary embodiments of OLEDs 5, the layers 52, 53, 54 of the OLEDs are applied to an edge surface of the substrate 51, or the light-guiding device 3. In the case of the embodiment illustrated with the aid of FIG. 9A, the contact surfaces 55, 56 are also arranged on the edge surface. In a departure therefrom, the contact surfaces 55, 56 of the embodiment shown in FIG. 9B are arranged substantially on opposite lateral surfaces of the substrate 51, or the light-guiding device 3. The contact surfaces 55, 56 thus also serve simultaneously as reflective surfaces 13.

As is illustrated in FIG. 9B, the contact surfaces 55, 56 can also extend around the edges of the substrate 51, or the light-guiding device 3, such that sections 58, 59 of the contact surfaces 55, 56 are located on the edge surface to which the OLED layers 52, 53, 54 are also applied.

OLEDs are generally sensitive to reactive air constituents such as oxygen and water vapour. It is therefore customary for OLEDs to be appropriately encapsulated. For the sake of clarity, the encapsulation is not illustrated in the figures. All arrangements known to the person skilled in the art can be used to encapsulate or house the OLED 5. In particular, reference may be made at this juncture to the German Patent Application of number 102 22 958.9 and to the prior art quoted there, whose disclosure is fully incorporated into the subject matter of the present invention.

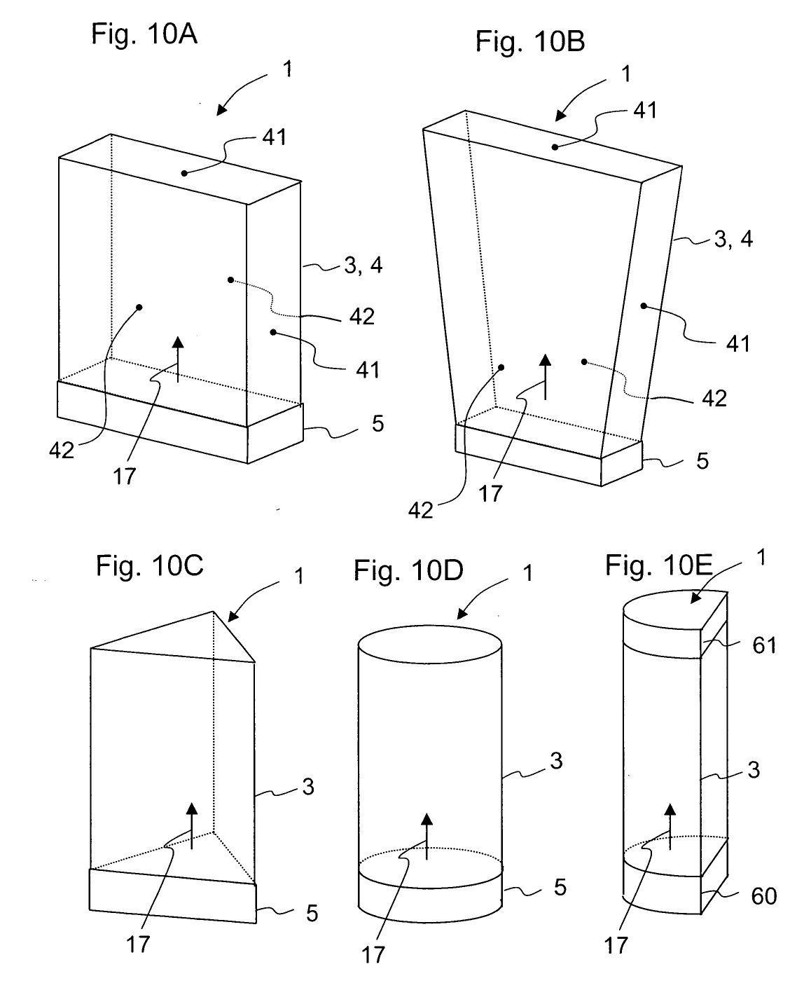

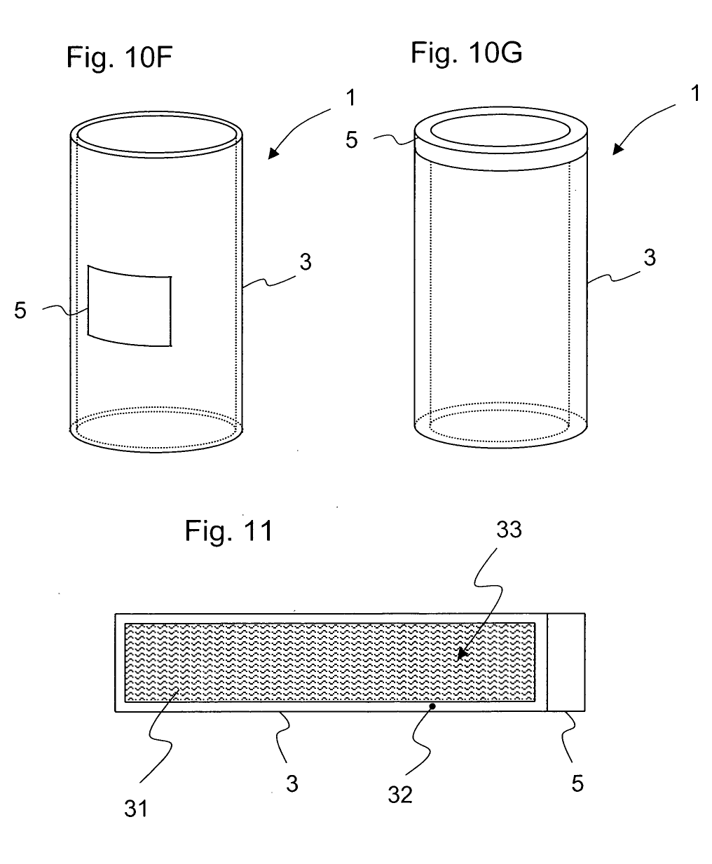

FIGS. 10A to 10G show embodiments of the luminous element 1 according to the invention with variously shaped light-guiding devices 3. Here, FIGS. 10A and 10B show embodiments in the case of which the light-guiding device 3 comprises a light guiding plate 4 with sides 42 and edge surfaces 41. In the embodiment shown in FIG. 10A, the sides 42 of the plate 4 have a rectangular or square shape, and so the plate 4 is of cuboid shape overall.

In the embodiment shown in FIG. 10B, the sides 42 are of trapezoidal shape, the cross section of the trapezoidal plate being enlarged here along the light guidance direction. Likewise, in accordance with a further embodiment, the cross section can also, however, diminish along the light guidance direction.

These shapes of light guiding plates 4 are, however, only exemplary. A multiplicity of other shapes are also conceivable and expedient for specific applications. For example, the plates can also be bent, or have curved rims.

FIGS. 10C to 10E show further embodiments, in the case of which the light-guiding device 3 is not plate-shaped. A luminous element with a prismatic light-guiding device 3 is illustrated in FIG. 10C. Here, the prism has a triangular base face or end face. However, the base face can also equally be in the shape of a quadrilateral or hexagon, for example. FIGS. 10D and 10E further show embodiments with a cylindrical, or semicylindrical light-guiding device 3. Furthermore, in the case of the embodiments of FIG. 10C and FIG. 10D, the OLED 5 is respectively arranged at one of the base faces or end faces of the light-guiding device 3.

The exemplary embodiment shown in FIG. 10E has a semicylindrical shape. Moreover, this luminous element comprises a number of OLEDs 60, 61 that can be coupled to the end faces of the light-guiding device.

The luminous element illustrated in FIG. 10F has a cylindrically tubular light-guiding device 3. Here, the OLED 5 is applied to the cylinder wall of the light-guiding device 3. In accordance with a development of this embodiment, the tubular light-guiding device 3 can also be designed for holding a fluid. Here, the fluid in the light-guiding device 3 can then itself serve as light guide. Such a refinement of the invention can be used, for example, for sensory applications and for monitoring levels for example.

The light-guiding device 3 also has a tubular shape in the case of the luminous element illustrated in FIG. 10G. In a departure from the embodiment shown in FIG. 10F, however, the OLED 5 is applied to the end face of the light-guiding device 3.

A tubular light-guiding device such as the exemplary embodiments of FIGS. 10F and 10G have can also be produced, for example, by bending flexible material. For example, to this end the light-guiding device 3 can comprise extremely thin glass, for example with a thickness of smaller than 150 μm, which is then bent into a tubular shape. Likewise, a composite material with extremely thin glass layers and polymer layers is also suitable, for example.

A further embodiment of the invention is illustrated diagrammatically in FIG. 11. Here, the light guiding-device 3 comprises a container with walls 32, and its interior 31 is filled or can be filled with a fluid 33. In particular, a liquid such as, for example, water or a gel can be used as fluid 33. Such an embodiment is particularly suitable given large dimensions of the light-guiding device 3 which need not here be solid, and so, for example, can be advantageously produced and is easy to transport.

A container-shaped light-guiding device 3 for holding liquids can also advantageously be used for sensory and monitoring applications, the liquid present in the container changing the conduction of light. A luminous element of such design can thus be used, for example, for measuring filling heights.

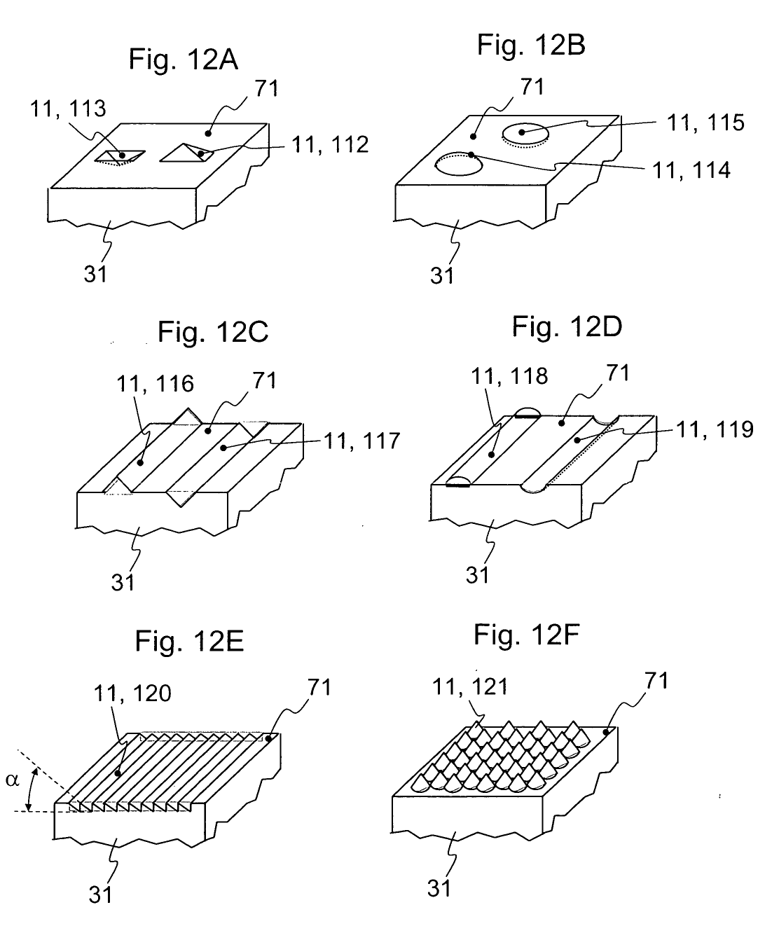

Reference is made below to FIGS. 12A to 12F, which show perspective views of sections from the light-scattering area 7 of the light-guiding device 3 with various shapes of light-scattering structures 11. The light-scattering structures 11 shown in FIG. 12A comprise pyramids 112 and pyramids 113 that are respectively raised and recessed with reference to the surface 71 of the light-scattering area. The pyramids are illustrated as regular pyramids with a quadrilateral base face. Likewise possible, however, are also tetrahedral pyramids, pyramids with a polygonal base face, or conical structures.

The section from the light-scattering area that is shown in FIG. 12B shows by way of example light-scattering structures in the shape of convex and concave lenses 114 and 115, respectively.

FIG. 12C shows a surface area which has light-scattering structures 11 in the shape of a raised prism 116 and a recessed prism 117, or a v-shaped notch 117. Finally, FIG. 12D shows a section of a light-scattering area with concave and convex cylindrical lenses 119 and 118, respectively.

Illustrated in FIGS. 12E and 12F are two exemplary embodiments of surface areas of the light-guiding device 3 with gratings as light-scattering structures 11. In the exemplary embodiment illustrated in FIG. 12E, a blazed multiline grating 120 is embossed into the surface 71 of the light-scattering area of the light-guiding device. The blaze angle α can be selected in accordance with the desired angular distribution of the light scattered out.

FIG. 12F shows an exemplary embodiment with a two-dimensional dot grating 121 as light-scattering structure 11. For its part, the dot grating comprises light-scattering structures arranged in the shape of a grating, conical structures being illustrated by way of example in FIG. 12F. In the case of the exemplary embodiment shown in FIG. 12F, the grating is, moreover, hexagonal, although it is self evident that, depending on what is required of the optical properties of the grating, it is also possible to select other shapes, for example with square or rectangular elementary cells.

The light-scattering structures 11 shown in FIGS. 12A to 12F and arranged on the surface 71 of one or more faces of the light-scattering area of a light-guiding device are only exemplary. Furthermore, the light-guiding device can have only one shape such as, for example, raised pyramids, or a number of shapes of light-scattering structures. Alternatively or in addition, the light-scattering area can also have light-scattering structures in the interior 31.

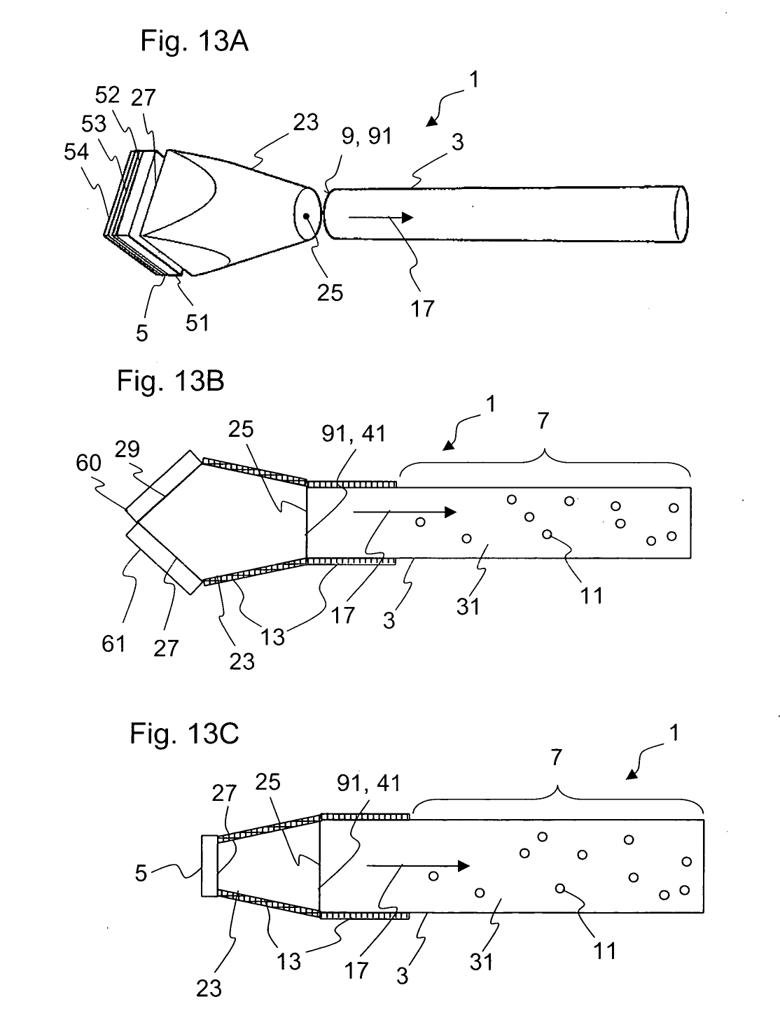

FIG. 13A shows an exploded illustration of an embodiment of a luminous element 1 according to the invention with a coupling element 23. The OLED 5 has a square shape and is coupled to a round light entry surface 91 of the cylindrical light-guiding device 3 by means of the coupling element 23 made of a transparent material. The coupling element 23 has two coupling surfaces 25 and 27, the coupling surface 25 being of round shape in accordance with the light entry surface 91, and the coupling surface 27 being of square shape in accordance with the shape of the light exit surface of the OLED 5. In this embodiment, the light entry surface 91 is smaller than the light exit surface of the OLED 5. In this case, the light of a large-area OLED is therefore coupled by the coupling element 23 into a light-guiding device 3 with a smaller cross section perpendicular to the light guidance direction 17. A higher luminance along the light-guiding device 3 is advantageously achieved in this way.

FIG. 13B shows a cross sectional view of a further embodiment of a luminous element with a coupling element 23. In this embodiment, the coupling element 23 has three coupling surfaces 25, 27 and 29. As in the embodiment, described with the aid of FIG. 13A, the coupling surface 25 is coupled to the light entry surface 91 of the light-guiding device 3. An OLED 60 or 61, respectively, is coupled in each case to the two other coupling surfaces 27 and 29, and so light of a number of OLEDs 60, 61 can be coupled into the light-guiding device 3 via the coupling element 23 in order to increase the luminosity. Again, the coupling element 23 can also be used for coupling to the light-guiding device OLEDs which shine in various colours.

Further surfaces of the coupling element which are not coupling surfaces also have a reflective layer 13 in this embodiment. In the case of this embodiment of a luminous element according to the invention, a section of the light-guiding device 3 adjoining the light entry surface 91 is, moreover, likewise provided with a reflective layer 13 and has no light-scattering structures. Furthermore, the light entry surface 91 is arranged at an edge surface 41.

Along the light guidance direction 17, the light-scattering area 7 therefore begins behind this first section. This can be useful, for example, for a concealed installation of the unit composed of coupling element 3 and OLEDs 60, 61, only the light-scattering area 7 being visible, and the other constituents of the luminous element 1 being arranged behind a cover.

Yet a further embodiment of an inventive luminous element 1 with a coupling element 23 is shown in FIG. 13C. In a departure from the embodiment illustrated in FIG. 13A, in the case of the embodiment shown in FIG. 13C the coupling surface 27 connected to the OLED 5 is smaller than the coupling surface 25 coupled to the light entry surface 91. Consequently, the coupling element 23 acts in the case of the embodiment shown in FIG. 13C as a distributor for the light emitted by the OLED 5. Here, the coupling element 23 can be used to distribute the light uniformly over a light entry surface that is greater than the luminous surface of the OLED 5. Moreover, in a way similar to the case of the luminous element illustrated in FIG. 13B, with this embodiment as well, a first section, adjoining the light entry surface 91, of the light-guiding device 3 is provided with a reflective layer 13, the light-scattering area 7 with light-scattering structures 11 adjoining this section in a direction along the light guidance direction.

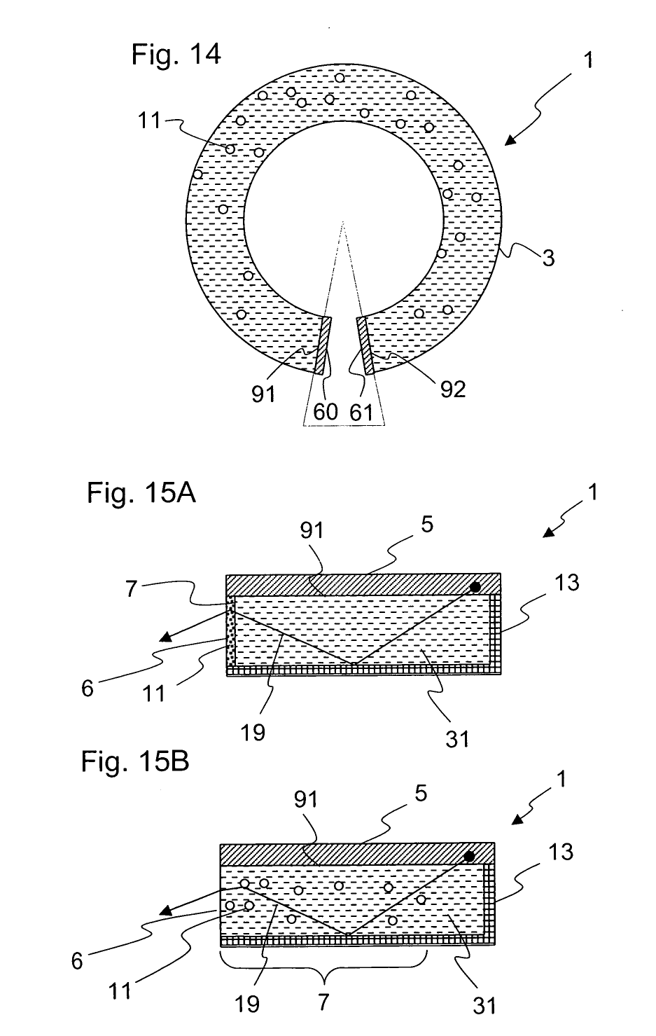

FIG. 14 shows an embodiment of a luminous element 1 with an annular light-guiding device 3. The light-guiding device 3 in this case forms an open ring with two end faces which serve as light entry surfaces 91, 92 for two OLEDs 60 and 61, respectively, coupled in each case to one of the light entry surfaces 91, 92. Given a suitable distribution of the light-scattering structures 11, such an arrangement can provide a uniformly luminous annular luminaire. Other than as shown in FIG. 14, the light-guiding device 3 can also have the shape of a closed ring, one or more OLEDs then being coupled to light entry surfaces on the ring surface.

In the abovedescribed embodiments of FIGS. 1 to 14, the light-scattering area 7 has a light exit surface which is larger than the light entry surface of the light-guiding device 3. By contrast, the light exit surface 6 is smaller than the light entry surface 91 in the case of the luminous elements 1 illustrated in cross sectional view in FIGS. 15A and 15B. In these embodiments, the light-guiding device 3 comprises a light guiding plate, one or more of the edge surfaces forming the light exit surface 6. One of the sides of the plate forms the light entry surface 91 to which the OLED 5 is coupled. In order to avoid an exit of light at other surfaces than the light exit surface 6, and to guide the light in the light-guiding device, these surfaces are provided with a reflective layer 13.

Because the light exit surface is smaller than the light entry surface, a concentration of the light entering at the light entry surface is achieved at the light exit surface, and thus so is an increase in the luminosity.

The two embodiments shown in FIGS. 15A and 15B differ from one another with regard to the arrangement of the light-scattering structures. In the case of the embodiment of the invention illustrated in FIG. 15A, the light-scattering structures 11 are arranged at or on the light exit side 6. In the case of the luminous element 1 shown in FIG. 15B, the light-scattering structures are arranged in the interior 31 along at least one section of the plate.

Such luminous elements can be used to produce high-luminosity luminous strips or slit lamps. By way of example, these can have a width in the range from ≦0.05 cm up to a few centimetres, depending on the thickness of the plate of the light-guiding device.

It is clear to the person skilled in the art that the invention is not limited to the embodiments described above, but rather can be varied in multivarious ways. In particular, the features of the individual exemplary embodiments can also be combined with one another. Again, the luminous elements described here can comprise yet further features. For example, colorants can be added to the light-guiding device and/or a substrate of the OLED in order to vary the colour sensation of the luminous element.

1-32. (canceled)

33. Luminous element with a light-guiding device in which light is guided by reflection, in particular, in the case of which the light-guiding device comprises at least one light-scattering area to which light-scattering structures can be applied,—in particular, to the surface of the light-scattering area, and at least one light entry surface, and at least one OLED is coupled to the light entry surface, characterized in that the OLED comprises a transparent substrate which is coupled to a light entry surface of the light-guiding device, the light-guiding device comprising a light guiding plate and the glass substrate being plate-shaped and being coupled with the aid of an edge surface to the light-guiding device.

34. Luminous element according to claim 33 wherein said light-scattering area comprises a light-scattering structure.

35. Luminous element according to claim 33, characterized in that the light-guiding device comprises a transparent material.

36. Luminous element according to claim 35, characterized in that the transparent material comprises one of the group consisting of glass and coated glass and glass laminate and glass plastic laminate and a fluid.

37. Luminous element according to claim 33, characterized in that the light entry surface is arranged at an edge surface of the light guiding plate.

38. Luminous element according to claim 33, characterized in that the light entry surface adjoins an edge surface of the plate.

39. Luminous element according to claim 33, in which the light-guiding device has an elongated, for example cylindrical or prismatic shape.

40. Luminous element according to claim 39, characterized in that the light entry surface comprises at least one end face.

41. Luminous element according to claim 39, characterized in that the light entry surface comprises at least one face at one of the ends of the light-guiding device.

42. Luminous element according to claim 33, characterized in that the light entry surface (91) is arranged on at least one side of the light guiding plate.

43. Luminous element according to claim 33, characterized in that the substrate of the OLED is flexible.

44. Luminous element according to claim 33, characterized in that the substrate comprises one of the group consisting of a polymer, extremely thin glass and a composite of extremely thin glass and polymer.

45. Luminous element according to claim 33, characterized in that a light entry area comprises the light entry surface.

46. Luminous element according to claim 45, characterized in that the light entry area comprises one of the group consisting of the OLED, at least one specular reflective surface and an optical grating, in particular a blaze grating.

47. Luminous element according to claim 33, characterized in that the OLED is of strip-shaped form.

48. Luminous element according to claim 47, characterized in that the OLED has contact surfaces which extend along the longitudinal direction of the OLED.

49. Luminous element according to claim 33, characterized in that the OLED is coupled to the light-guiding device by a transparent bonded joint, in particular with the aid of a transparent bonded joint matched for refractive power.

50. Luminous element according to claim 33, characterized in that the light entry surface is arranged obliquely to the light guidance direction.

51. Luminous element according to claim 33, characterized in that the light entry surface is curved.

52. Luminous element according to claim 33, characterized in that the light-scattering structure is arranged in the interior of the light-guiding device.

53. Luminous element according to claim 33, in which the light-scattering structure comprises a roughened surface area.

54. Luminous element according to claim 53, in which the roughness increases along the light guidance direction.

55. Luminous element according to claim 33, characterized in that the light-scattering structure is coloured.

56. Luminous element according to claim 33, characterized in that the light-scattering structure comprises one of the group consisting of a raised pyramid structure and a recessed pyramid structure and a convex lens and a concave lens and a raised prism and a recessed prism and a convex cylindrical lens and a concave cylindrical lens.

57. Luminous element according to claim 33, characterized in that the light-scattering structure comprises an optical grating.

58. Luminous element according to claim 33, characterized by a number of OLEDs coupled to light entry surfaces.

59. Luminous element according to claim 58, characterized in that the several OLEDs emit light of different colour.

60. Luminous element according to claim 33, characterized in that the OLED emits white light.

61. Luminous element according to claim 33, characterized in that the light-scattering area has a light exit surface which is larger than the light entry surface of the light-guiding device.

62. Luminous element according to claim 33, characterized in that the OLED is coupled to the light entry surface via a coupling element.

63. Luminous element according to claim 62, characterized in that a number of OLEDs are coupled to the light entry surface via the coupling element.

64. Luminous element according to claim 62, characterized in that the coupling element has at least two different coupling surfaces.

65. Luminous element according to claim 33 characterized in that the light-guiding device has an annularly bent shape.

66. Luminous element according to claim 33, characterized in that the light-guiding device has a cylindrical, semicylindrical, tubular, conical or prismatic form.

67. Luminous element with a light-guiding device in which light is guided by reflection, in particular, in the case of which the light-guiding device comprises at least one light-scattering area which has at least one light-scattering structure, and at least one light entry surface, and at least one OLED is coupled to the light entry surface, characterized in that the light-guiding device has a light exit surface which comprises at least one edge surface of a light guiding plate, and the light entry surface is arranged on at least one side of the light guiding plate.
